(19) United States
(12) Patent Application Publication
(10) Pub. No.: US 2021/0193439 A1
(43) Pub. Date: Jun. 24, 2021

(54) PLASMA PROCESSING APPARATUS

(71) Applicant: TOKYO ELECTRON LIMITED, Tokyo (JP)

(72) Inventors: Mayo UDA, Miyagi (JP); Mitsunori OHATA, Miyagi (JP)

(73) Assignee: TOKYO ELECTRON LIMITED, Tokyo (JP)

(21) Appl. No.: 17/130,770

(22) Filed: Dec. 22, 2020

(30) Foreign Application Priority Data
Dec. 23, 2019 (JP) 2019-231039

(51) Int. Cl. H01J 37/32

(52) U.S. Cl. CPC H01J 37/32449; H01J 37/3211

(57) ABSTRACT

A plasma processing apparatus includes a chamber, an antenna assembly, a primary coil, a radio frequency (RF) power supply and a gas shower. The chamber includes a sidewall and a ceiling plate having a central opening. The the sidewall and the ceiling plate define a plasma processing space. The antenna assembly is disposed above the ceiling plate. The antenna assembly includes a central region, a first peripheral region surrounding the central region, and a second peripheral region surrounding the first peripheral region. The central region and the first peripheral region vertically overlap the central opening. The primary coil is disposed in the second peripheral region. The RF power supply is configured to supply an RF signal to the primary coil. The gas shower is disposed in the central opening and has a bottom portion exposed to the plasma processing space, the bottom portion having bottom gas injection holes.

### CROSS-REFERENCE TO RELATED APPLICATIONS

This application claims priority to Japanese Patent Application No. 2019-231039, filed on Dec. 23, 2019, the entire contents of which are incorporated herein by reference.

### TECHNICAL FIELD

The present disclosure relates to a plasma processing apparatus.

### BACKGROUND

An inductively coupled plasma (ICP) type plasma processing apparatus is known as an example of a plasma processing apparatus. The ICP type plasma processing apparatus employs, for example, a technique for exciting a processing gas by generating an induced electric field in a processing chamber using a coil-shaped outer antenna for supplying a radio frequency power and an inductively coupled coil-shaped inner antenna that is concentric with the outer antenna (see, e.g., Japanese Patent Application Publication No. 2019-067503).

### SUMMARY

The present disclosure provides a plasma processing apparatus capable of improving controllability of gas distribution on a substrate.

In accordance with an aspect of the present disclosure, there is provided a plasma processing apparatus including: a chamber including a sidewall and a ceiling plate having a central opening, the sidewall and the ceiling plate defining a plasma processing space; an antenna assembly disposed above the ceiling plate, the antenna assembly including a central region, a first peripheral region and a second peripheral region, the first peripheral region surrounding the central region, and the second peripheral region surrounding the first peripheral region, the central region and the first peripheral region vertically overlapping the central opening; a primary coil disposed in the second peripheral region; a radio frequency (RF) power supply configured to supply an RF signal to the primary coil; and a gas shower disposed in the central opening, the gas shower having a bottom portion exposed to the plasma processing space, the bottom portion having bottom gas injection holes.

### BRIEF DESCRIPTION OF THE DRAWINGS

The objects and features of the present disclosure will become apparent from the following description of embodiments, given in conjunction with the accompanying drawings, in which:

FIG. 1 shows an example of a plasma processing system according to a first embodiment of the present disclosure;

FIG. 2 is a schematic perspective view showing an example of an antenna according to the first embodiment;

FIG. 3 shows an example of an arrangement of an inner coil and an outer coil according to the first embodiment;

FIG. 4 shows an example of a gas shower according to the first embodiment;

FIGS. 5 and 6 show examples of simulation results in a first comparative example;

FIGS. 7 and 8 show examples of simulation results in the first embodiment;

FIG. 9 shows an example of a plasma processing system according to a second embodiment of the present disclosure;

FIG. 10 shows an example of a configuration of a nozzle in a second comparative example;

FIG. 11 shows an example of a configuration of a gas shower in a first modification of the second embodiment;

FIG. 12 shows an example of a simulation result in the second comparative example;

FIG. 13 shows an example of a simulation result in the first modification of the second embodiment;

FIGS. 14 to 16 show examples of simulation results in the second comparative example;

FIGS. 17 to 19 show examples of simulation results in the first modification of the second embodiment;

FIG. 20 shows an example of a simulation result of an electromagnetic field in a third comparative example;

FIG. 21 shows an example of a simulation result of an electromagnetic field in a second modification of the second embodiment;

FIG. 22 shows an example of a simulation result of an electromagnetic field in the third comparative example; and

FIG. 23 shows an example of a simulation result of an electromagnetic field in the second modification of the second embodiment.

### DETAILED DESCRIPTION

Hereinafter, embodiments of a plasma processing apparatus of the present disclosure will be described in detail with reference to the accompanying drawings. The present disclosure is not limited by the following embodiments.

In an inductively coupled plasma (ICP) type plasma processing apparatus, an induced electric field is generated in a processing chamber using a coil-shaped antenna. Therefore, a gas injector for introducing a processing gas into the processing chamber is disposed at a central portion of a ceiling plate of the processing chamber while avoiding a portion where the antenna is disposed. However, the gas injector introduces the processing gas into a small-diameter area of the processing chamber. Thus, the distribution of the gas that is introduced downward has a convex shape at a central portion of a substrate, and is difficult to control. Accordingly, it is desireable to improve the controllability of the gas distribution on the substrate.

(Configuration of the Plasma Processing System 1 According to the First Embodiment)

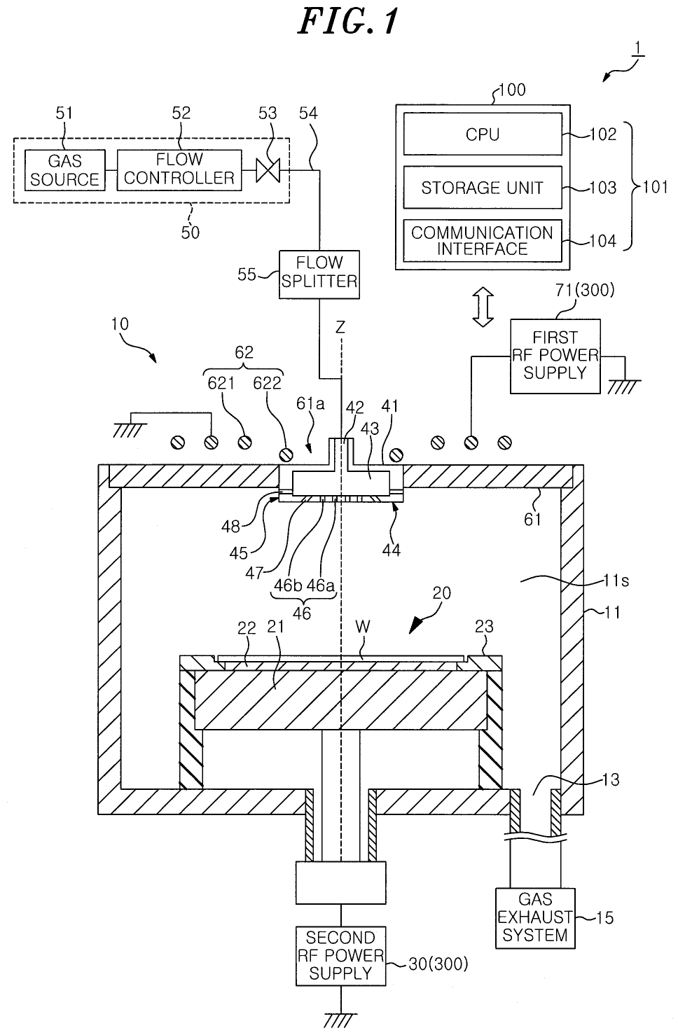

FIG. 1 shows an example of a plasma processing system according to the first embodiment of the present disclosure. As shown in FIG. 1, in one embodiment, the plasma processing system 1 includes a plasma processing apparatus 10 and a controller 100. The plasma processing apparatus 10 includes a plasma processing chamber 11, a gas supply unit 50, a radio frequency (RF) power supply unit 300, and a gas exhaust system 15. The plasma processing apparatus 10 further includes a substrate support 20, a gas shower 41, and an antenna 62. The substrate support 20 is disposed at a lower area of a plasma processing space 11s in the plasma processing chamber 11. The plasma processing space 11s is defined by a sidewall and a dielectric window 61 (ceiling plate) of the plasma processing chamber 11. The gas shower 41 is disposed above the substrate support 20 and is fitted to a central opening 61a of the dielectric window 61. The antenna 62 is disposed on or above the plasma processing chamber 11 (the dielectric window 61).

The substrate support 20 is configured to support the substrate W in the plasma processing space 11s. In one embodiment, the substrate support 20 includes a lower electrode 21, an electrostatic chuck 22, and an edge ring 23. The electrostatic chuck 22 is disposed on the lower electrode 21 and is configured to support the substrate W on an upper surface of the electrostatic chuck 22. The lower electrode 21 functions as a bias electrode. The edge ring 23 is disposed to surround the substrate W on an upper surface of a peripheral portion of the lower electrode 21. Although it is not shown, in one embodiment, the substrate support 20 may include a temperature control module configured to adjust at least one of the electrostatic chuck 22 and the substrate W to a target temperature. The temperature control module may include a heater, a flow channel, or a combination thereof. A temperature control fluid such as a coolant or a heat transfer gas flows through the flow channel.

The gas shower 41 is configured to supply one or more processing gases from the gas supply unit 50 to the plasma processing space 11s. In one embodiment, the gas shower 41 has a gas inlet 42, a gas diffusion space 43, and a plurality of bottom gas injection holes 46 and 47 and a plurality of side gas injection holes 48. The gas shower 41 has a structure in which a horizontal dimension is greater than a vertical dimension. The bottom gas injection holes 46 and 47 and the side gas injection holes 48 are in fluid communication with the gas supply unit 50 and the gas diffusion space 43. Further, the bottom gas injection holes 46 and 47 and the side gas injection holes 48 are in fluid communication with the gas diffusion space 43 and the plasma processing space 11s. In one embodiment, the gas shower 41 is configured to supply one or more processing gases from the gas inlet 42 to the plasma processing space 11s through the gas diffusion space 43, the bottom gas injection holes 46 and 47, and the side gas injection holes 48.

The gas supply unit 50 may include one or more gas sources 51, one or more flow controllers 52, a valve 53, a line 54, and a flow splitter (gas flow distributor) 55. In one embodiment, the gas supply unit 50 is configured to supply one or more processing gases from the corresponding gas sources 51 to the gas shower 41 through the corresponding flow controllers 52, and the valve 53, the line 54, and the flow splitter 55. Each of the flow controllers 52 may include, for example, a mass flow controller (MFC) or a pressure-control type flow controller.

The RF power supply unit 300 is configured to supply an RF power, e.g., one or more RF signals, to the lower electrode 21 and the antenna 62. Accordingly, plasma is generated from one or more processing gases supplied to the plasma processing space 11s. Therefore, the RF power supply unit 300 can function as at least a part of a plasma generation unit configured to generate plasma from one or more processing gases in the plasma processing chamber. In one embodiment, the RF power supply unit 300 includes a first RF power supply 71 and a second RF power supply 30.

The first RF power supply 71 includes a first RF generator and a first matching circuit. In one embodiment, the first RF power supply 71 is configured to supply a first RF signal from the first RF generator to the antenna 62 through the first matching circuit. In one embodiment, the first RF signal is a RF source signal having a frequency within a range of 27 MHz to 100 MHz.

The second RF power supply 30 includes a second RF generator and a second matching circuit. In one embodiment, the second RF power supply 30 is configured to supply a second RF signal from the second RF generator to the lower electrode 21 through the second matching circuit. In one embodiment, the second RF signal is a RF bias signal having a frequency within a range of 400 kHz to 13.56 MHz.

The antenna 62 includes an outer coil 621 and an inner coil 622 that are arranged to be coaxial with the gas shower 41. The inner coil 622 is disposed around the gas shower 41 to surround the gas shower 41. The outer coil 621 is disposed around the inner coil 622 to surround the inner coil 622. The outer coil 621 functions as a primary coil to which the first RF power supply 71 is connected. In one embodiment, the outer coil 621 is a planar coil and has a substantially circular spiral shape. The inner coil 622 functions as a secondary coil that is inductively coupled to the primary coil. In other words, the inner coil 622 is not connected to the first RF power supply 71. In one embodiment, the inner coil 622 is a planar coil and has a substantially circular ring shape. In one embodiment, the inner coil 622 is connected to a variable capacitor, and a direction or a magnitude of a current flowing through the inner coil 622 is controlled by controlling a capacitance of the variable capacitor. The outer coil 621 and the inner coil 622 may be arranged at the same height or at different heights. In one embodiment, the inner coil 622 is located lower than the outer coil 621.

The gas exhaust system 15 may be connected to, e.g., a gas exhaust port 13 disposed at a bottom portion of the plasma processing chamber 11. The gas exhaust system 15 may include a pressure valve and a vacuum pump. The vacuum pump may include a turbo molecular pump, a roughing pump, or a combination thereof.

In one embodiment, the controller 100 processes computer-executable instructions for causing the plasma processing apparatus 10 to perform various processes described in the present disclosure. The controller 100 may be configured to control the individual components of the plasma processing apparatus 10 to perform various processes described herein. In one embodiment, the controller 100 may be partially or entirely included in the plasma processing apparatus 10. The controller 100 may include, e.g., a computer 101. The computer 101 may include, e.g., a central processing unit (CPU) 102, a storage unit 103, and a communication interface 104. The CPU 102 may be configured to perform various control operations based on programs stored in the storage unit 103. The storage unit 103 may include a random access memory (RAM), a read only memory (ROM), a hard disk drive (HDD), a solid state drive (SSD), or a combination thereof. The communication interface 104 may communicate with the plasma processing apparatus 10 through a communication line such as a local area network (LAN) or the like.

(Structure of the Antenna 62)

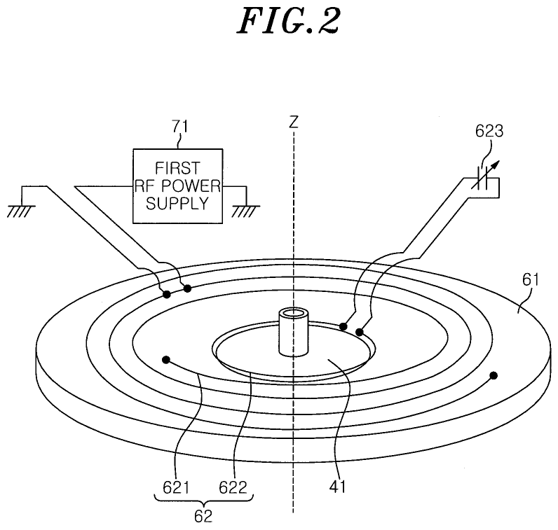

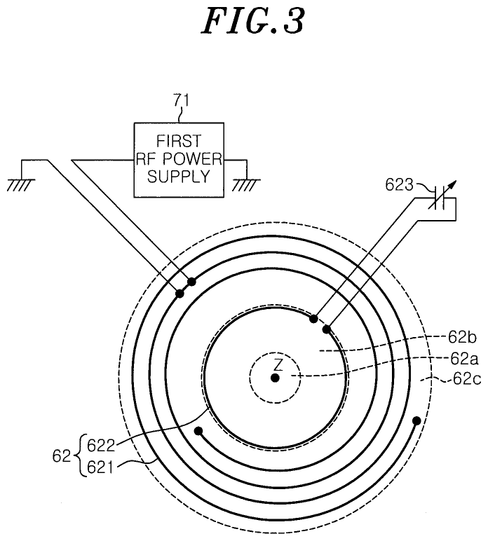

Next, the antenna 62 will be described in detail with reference to FIGS. 2 and 3. FIG. 2 is a schematic perspective view showing an example of the antenna according to the first embodiment. FIG. 3 shows an example of an arrangement of the inner coil and the outer coil according to the first embodiment. As shown in FIGS. 2 and 3, the antenna 62 is an example of an antenna assembly disposed above the dielectric window 61, and the antenna assembly includes a central region 62a, a first peripheral region 62b and a second peripheral region 62c. The first peripheral region 62b surrounds the central region 62a, and the second peripheral region 62c surrounds the first peripheral region 62b. The central region 62a and the first peripheral region 62b vertically overlap the central opening 61a of the dielectric window 61. Further, the gas shower 41 is disposed in the central opening 61a.

The outer coil 621 is wound two or more turns in a substantially circular spiral shape. The outer coil 621 is disposed in the second peripheral region 62c such that the central axis of the outer shape of the outer coil 621 coincides with the Z-axis. The inner coil 622 is formed in, e.g., a substantially circular ring shape. The inner coil 622 is disposed above the dielectric window 61 such that the central axis of the inner coil 622 coincides with the Z-axis. Further, the inner coil 622 is disposed at a position in the first peripheral region 62b to allow the inner coil 622 to vertically overlap with an outer peripheral portion of the gas shower 41 or at a position in the first peripheral region 62b to allow the inner coil 622 to be disposed at an outer side of the outer peripheral portion of the gas shower 41. Since it is considered that abnormal discharge occurs in the gas diffusion space 43 when a horizontal dimension of the gas shower 41 increases up to a position where the gas shower 41 is vertically overlapped with the outer coil 621, it is preferable that the gas shower 41 is arranged not to be overlapped with the outer coil 621.

The outer coil 621 and the inner coil 622 are planar coils and are arranged above a bottom surface of the dielectric window 61, which is the boundary surface with the plasma processing space 11s, to be substantially parallel to a surface of the substrate W placed on the electrostatic chuck 22. Further, a distance between the outer coil 621 and the bottom surface of the dielectric window 61 is different from a distance between the inner coil 622 and the bottom surface of the dielectric window 61. For example, the distance between the inner coil 622 and the bottom surface of the dielectric window 61 is shorter than the distance between the outer coil 621 and the bottom surface of the dielectric window 61. In another example, the distance between the outer coil 621 and an upper surface of the dielectric window 61 and the distance between the inner coil 622 and the upper surface of the dielectric window 61 may be the same. In still another example, the distance between the outer coil 621 and the upper surface of the dielectric window 61 may be longer than the distance between the inner coil 622 and the upper surface of the dielectric window 61. In still another example, the distance between the outer coil 621 and the bottom surface of the dielectric window 61 and the distance between the inner coil 622 and the bottom surface of the dielectric window 61 may be independently changed by a driving unit (not shown). FIG. 3 shows an example of the arrangement of the inner coil 622 and the outer coil 621 when viewed from the Z-axis direction. The inner coil 622 has a circular shape along the outer peripheral portion of the gas shower 41 and is disposed in the first peripheral region 62b such that the center of the circle coincides with the Z-axis.

The outer coil 621 includes a wire having two open ends. The first RF power supply 71 is connected to a central point (first contact point) of the wire forming the outer coil 621 or to a vicinity (second contact point) of the central point, and a RF source signal (RF power) is supplied from the first RF power supply unit 71 to the outer coil 621. The vicinity of the central point of the wire forming the outer coil 621 is grounded. The outer coil 621 is configured to resonate at a frequency having a wavelength that is half of a wavelength z of the RF source signal supplied from the first RF power supply 71. In other words, the outer coil 621 functions as a planar helical resonator. A voltage generated in the wire forming the outer coil 621 is distributed such that it becomes the minimum near the central point of the wire and becomes the maximum at both ends of the wire. Further, a current generated in the wire forming the outer coil 621 is distributed such that it becomes the maximum near the central point of the wire and becomes the minimum at both ends of the wire. The frequency and the power of the RF source signal supplied from the first RF power supply 71 to the outer coil 621 may be changed. The frequency and the power of the RF source signal supplied from the first RF power supply 71 to the outer coil 621 are controlled by the controller 100.

Both ends of a wire forming the inner coil 622 are connected to each other through a capacitor 623. In other words, the inner coil 622 has a wire having two ends and the capacitor 623 connected to the two ends. The capacitor 623 is a variable capacitor. The capacitor 623 may be a capacitor having a fixed capacitance. The inner coil 622 is inductively coupled with the outer coil 621. The current flows through the inner coil 622 in a direction to cancel a magnetic field generated by the current flowing through the outer coil 621. It is possible to control the direction or the magnitude of the current flowing through the inner coil 622 with respect to the current flowing through the outer coil 621 by controlling the capacitance of the capacitor 623. The capacitance of the capacitor 623 is controlled by the controller 100.

A magnetic field is generated in the Z-axis direction by the current flowing through the outer coil 621 and the current flowing through the inner coil 622, and an induced electric field is generated in the plasma processing chamber 11 by the magnetic field. Due to the induced electric field generated in the plasma processing chamber 11, the processing gas supplied from the gas shower 41 into the plasma processing chamber 11 is turned into plasma. Then, predetermined processing such as etching is performed on the substrate W on the electrostatic chuck 22 by ions or active species contained in the plasma.

(Gas Injection Holes of the Gas Shower 41)

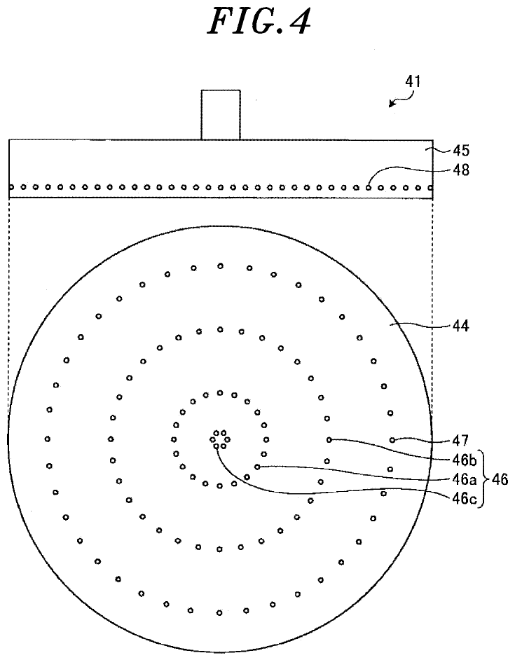

Next, the gas injection holes of the gas shower 41 will be described with reference to FIG. 4. FIG. 4 shows an example of the gas shower according to the first embodiment. As shown in FIG. 4, the plurality of bottom gas injection holes 46 and 47 are formed in a bottom portion 44 of the gas shower 41. The bottom gas injection holes 46 include, e.g., a plurality of bottom gas injection holes 46a, 46b, and 46c, arranged on the respective circumferences of concentric circles having different diameters. The bottom gas injection holes 47 are arranged on the circumference of a circle concentric with the circles respectively formed by the bottom gas injection holes 46a, 46b, and 46c, while being disposed at the outer side of the bottom gas injection holes 46a, 46b, and 46c. In other words, the bottom gas injection holes 46a, 46b, 46c, and 47 are arranged on the respective circumferences of concentric circles at equal intervals, for example. The bottom gas injection holes 46a, 46b, and 46c are formed to extend in the vertical direction, i.e., in the Z-axis direction of the plasma processing chamber 11. The bottom gas injection holes 47 are formed to extend obliquely toward the outer peripheral side, for example. In FIG. 1, the bottom gas injection holes 46c are omitted.

Further, the plurality of side gas injection holes 48 are formed at a side portion 45 of the gas shower 41. The side gas injection holes 48 are arranged on the circumference along the side portion 45 of the gas shower 41 at equal intervals, for example. The side gas injection holes 48 are formed to extend in a horizontal direction, i.e., in a direction perpendicular to the side portion 45. The bottom gas injection holes 46 and 47 and the side gas injection holes 48 may be arranged in a different manner, for example, in multiple rows or in a zigzag shape, and are not necessarily arranged at equal intervals. Further, the gas shower 41 is disposed such that the side gas injection holes 48 are exposed to the plasma processing space 11s.

Further, the bottom gas injection holes 46 and 47 have a first hole diameter of 0.05 mm to 1.5 mm and the side gas injection holes 48 have a second hole diameter of 0.05 mm to 1.5 mm, for example. The first hole diameter may be equal to or different from the second hole diameter.

(Simulation Result)

Next, the simulation results of the first embodiment and a first comparative example will be described with reference to FIGS. 5 to 8. In the first comparative example, the simulation was performed on an ICP type plasma processing apparatus in which a gas injector is disposed at the central portion of the dielectric window 61 of the plasma processing chamber 11. The gas injector has a structure in which a vertical dimension is greater than a horizontal dimension.

<Simulation Conditions>

Chamber pressure: 6.67 Pa (50 mTorr)

Processing gas: Ar=500 sccm

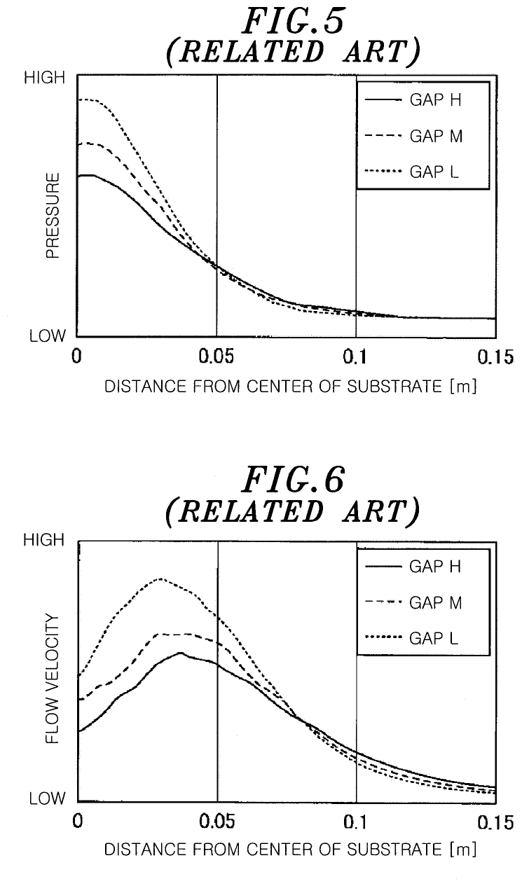

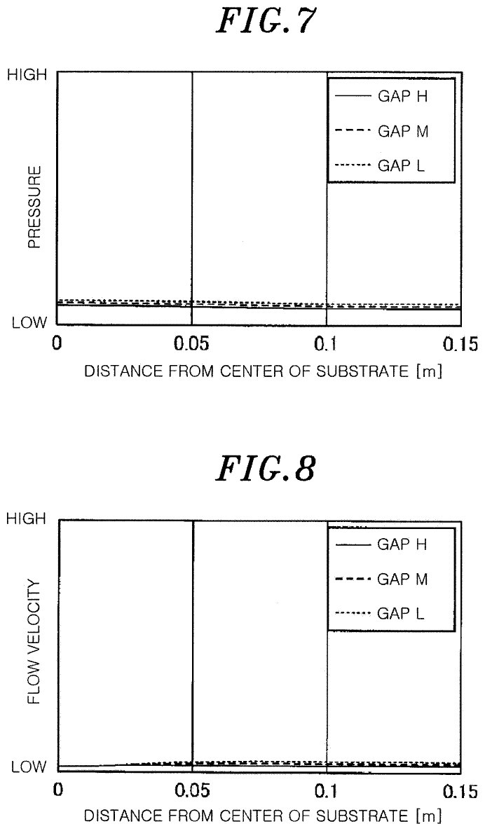

FIGS. 5 and 6 show examples of the simulation results in the first comparative example. FIGS. 7 and 8 show examples of the simulation results in the first embodiment. FIGS. 5 and 6 show the distribution of a pressure and the distribution of a flow velocity on the substrate W for each distance between the substrate W and the dielectric window 61 in the simulation of the first comparative example. FIGS. 7 and 8 show the distribution of a pressure and the distribution of a flow velocity on the substrate W for each distance between the substrate W and the dielectric window 61 in the simulation of the first embodiment. The distances between the substrate W and the dielectric window 61 are represented by “Gap H” corresponding to “high,” “Gap M” corresponding to “middle,” and “Gap L” corresponding to “low” in FIGS. 5 to 8.

According to the simulation results for the pressure on the substrate W between the first comparative example and the first embodiment, in the first comparative example shown in FIG. 5, the pressure is highest near the center of the substrate W and decreases toward the peripheral portion of the substrate W. In other words, the pressure distribution has a convex shape at the central portion. In contrast, in the first embodiment shown in FIG. 7, the pressure distribution is substantially uniform from the center of the substrate W to the peripheral portion of the substrate W.

According to the simulation results for the flow velocity on the substrate W between the first comparative example and the first embodiment, in the first comparative example shown in FIG. 6, the flow velocity is highest near a portion separated from the center of the substrate W by a distance of about 3 cm to 4 cm and decreases toward the peripheral portion of the substrate W. In other words, the flow velocity distribution has a convex shape at the central portion. In contrast, in the first embodiment shown in FIG. 8, the flow velocity distribution is substantially uniform from the center of the substrate W to the peripheral portion of the substrate W. In other words, in the first embodiment, the tendency in which the pressure distribution and the flow velocity distribution have a convex shape at the central portion can be suppressed using the gas shower 41. In other words, the controllability of the gas distribution on the substrate W can be improved.

(Configuration of the Plasma Processing System 2 According to the Second Embodiment)

In the first embodiment, the gas shower 41 has one gas diffusion space 43. However, it is also possible to divide the gas diffusion space 43 into a plurality of regions to distribute and control the flow amount of the processing gas to be supplied to each region. Such a case will be described as the second embodiment. Further, such a structure is referred to as a “radial distribution control (RDC) structure.” Like reference numerals will be given to like parts as those of the first embodiment, and the redundant description on the same configuration and operation will be omitted.

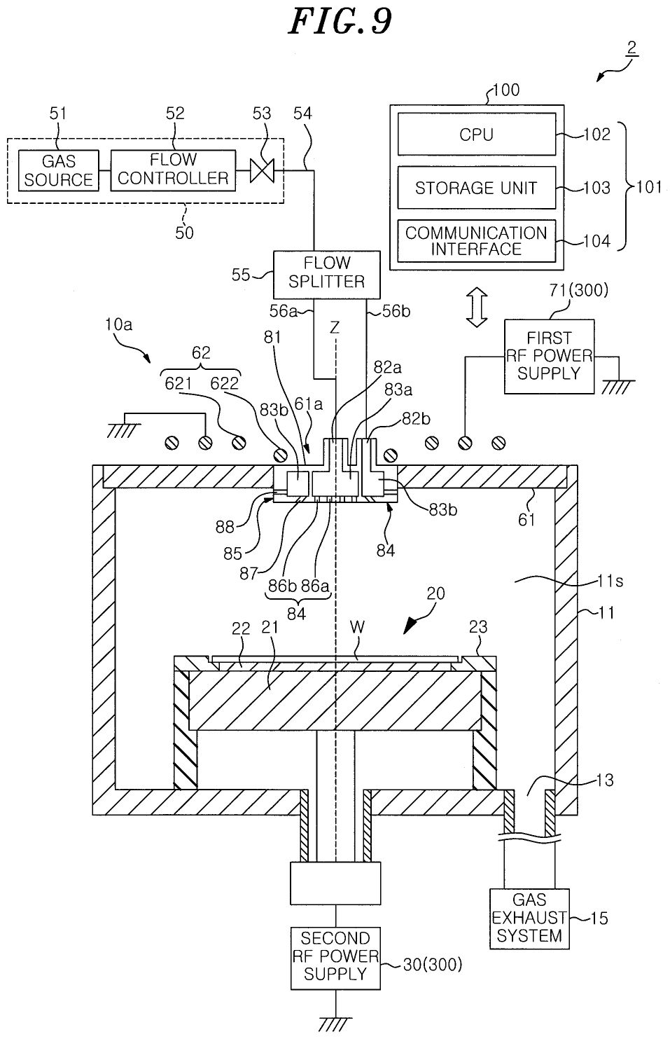

FIG. 9 shows an example of a plasma processing system according to the second embodiment of the present disclosure. The plasma processing system 2 shown in FIG. 9 is different from the plasma processing system 1 according to the first embodiment in that it includes a plasma processing apparatus 10a instead of the plasma processing apparatus 10. Further, the plasma processing apparatus 10a is different from the plasma processing apparatus 10 in that it includes a gas shower 81 instead of the gas shower 41.

The gas shower 81 has gas inlets 82a and 82b, gas diffusion spaces 83a and 83b, and a plurality of bottom gas injection holes 86 and 87 and a plurality of side gas injection holes 88. The arrangement of the bottom gas injection holes 86 and 87 and the side gas injection holes 88 of the gas shower 81 may be the same as the arrangement of the gas shower 41 shown in FIG. 4, for example. In other words, the arrangement of the bottom gas injection holes 86a, 86b, and 87 and the side gas injection holes 88 corresponds to the arrangement of the bottom gas injection holes 46a, 46b, and 47 and the side gas injection holes 48 shown in FIG. 4. In the gas shower 81 shown in FIG. 9, the bottom gas injection holes corresponding to the bottom gas injection holes 46c of the gas shower 41 are not illustrated for simplicity of description. However, the gas shower 81 may have the bottom gas injection holes corresponding to the bottom gas injection holes 46c of the gas shower 41.

The bottom gas injection holes 86 are formed in a bottom portion 84 of the gas shower 81. The bottom gas injection holes 86 include, e.g., a plurality of bottom gas injection holes 86a and 86b arranged on the respective circumferences of concentric circles having different diameters. The bottom gas injection holes 86a and 86b are in fluid communication with the gas diffusion space 83a and the gas supply unit 50 connected thereto through the gas inlet 82a. Further, the bottom gas injection holes 86a and 86b are in fluid communication with the gas diffusion space 83a and the plasma processing space 11s. The bottom gas injection holes 86a and 86b are formed to extend in the vertical direction, i.e., in the Z-axis direction of the plasma processing chamber 11.

The bottom gas injection holes 87 are formed in the bottom portion 84 of the gas shower 81. The bottom gas injection holes 87 are arranged on the circumference of a circle concentric with other circles respectively formed by the bottom gas injection holes 86a and 86b while being disposed at the outer side of the bottom gas injection holes 86a and 86b. The bottom gas injection holes 87 are in fluid communication with the gas diffusion space 83b and the gas supply unit 50 connected thereto through the gas inlet 82b. Further, the bottom gas injection holes 87 are in fluid communication with the gas diffusion space 83b and the plasma processing space 11s. The bottom gas injection holes 87 are formed to extend obliquely toward the outer peripheral side, for example.

The side gas injection holes 88 are arranged on the circumference of the gas shower 81 along a side portion 85 of the gas shower 81 at equal intervals, for example. The side gas injection holes 88 are in fluid communication with the gas diffusion space 83b and the gas supply unit 50 connected thereto through the gas inlet 82b. Further, the side gas injection holes 88 are in fluid communication with the gas diffusion space 83b and the plasma processing space 11s. The side gas injection holes 88 are formed to extend in the horizontal direction, i.e., in a direction perpendicular to the side portion 85. Similar to the first embodiment, the bottom gas injection holes 86, 87 and the side gas injection holes 88 may be arranged in a different manner, for example, in multiple rows or in a zigzag shape, and are not necessarily arranged at equal intervals. Similar to the gas shower 41, the gas shower 81 is disposed such that the side gas injection holes 88 are exposed to the plasma processing space 11s.

The gas inlets 82a and 82b are respectively connected to the flow splitter 55 through lines 56a and 56b. The flow splitter 55 is configured to distribute and control the flow rate of the processing gas. The flow splitter 55 may be a gas box or the like as long as it is configured to change the flow ratio of the processing gas supplied to the gas diffusion spaces 83a and 83b.

(Simulation Results)

Next, the simulation results of a second comparative example and a first modification of the second embodiment will be described with reference to FIGS. 10 to 19. In the second comparative example, the simulation was performed on an ICP type plasma processing apparatus in which a gas injector is disposed at the center of the dielectric window 61 of the plasma processing chamber 11.

First, the structures of the gas injector and the gas shower used in the simulation of the second comparative example and the first modification of the second embodiment will be described with reference to FIGS. 10 and 11. FIG. 10 shows an example of a configuration of a nozzle in the second comparative example. As shown in FIG. 10, a gas injector 200 of the second comparative example has two nozzle systems in the vertical direction (center) and the horizontal direction (side), and the processing gas is supplied to the plasma processing space 11s through the two nozzle systems.

FIG. 11 shows an example of a configuration of a gas shower in the first modification of the second embodiment. As shown in FIG. 11, the gas shower 201 of the first modification of the second embodiment has the same RDC structure as that of the gas shower 81, but is different from the gas shower 81 in that it has four gas diffusion spaces so that the processing gas is supplied through four gas injection hole systems. That is, the gas shower 201 is configured to supply the processing gas to the plasma processing space 11s through the four (center, middle, edge, and side) gas injection hole systems.

Specifically, the gas shower 201 has a first diffusion space disposed at the center of the gas shower 201, a second diffusion space surrounding the first diffusion space, a third diffusion space surrounding the second diffusion space, and a fourth diffusion space surrounding the third diffusion space. Further, the first diffusion space, the second diffusion space, the third diffusion space, and the fourth diffusion space are formed in the gas shower 201 but are not in fluid communication with each other. The gas injection holes of the gas shower 201 are the same as those of the gas shower 41 shown in FIG. 4 or the gas shower 81. In the case of applying the gas injection holes of the gas shower 81 to the gas injection holes of the gas shower 201, the bottom gas injection holes 86a (center holes) are in fluid communication with the first diffusion space. Similarly, the bottom gas injection holes 86b (middle holes) are in fluid communication with the second diffusion space, and the bottom gas injection holes 87 (edge holes) are in fluid communication with the third diffusion space. The side gas injection holes 88 (side holes) are in fluid communication with the fourth diffusion space.

In other words, in the gas shower 201, the bottom gas injection holes 86a and 86b being in fluid communication with the same gas diffusion space 83a in the gas shower 81 are in fluid communication with different gas diffusion spaces, i.e., the first diffusion space and the second diffusion space. Similarly, in the gas shower 201, the bottom gas injection holes 87 and the side gas injection holes 88 being in fluid communication with the same gas diffusion space 83b in the gas shower 81 are in fluid communication with different gas diffusion spaces, i.e., the third diffusion space and the fourth diffusion space.

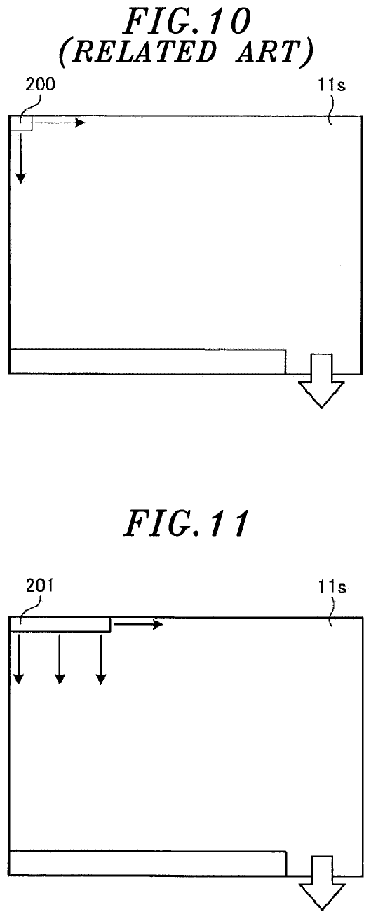

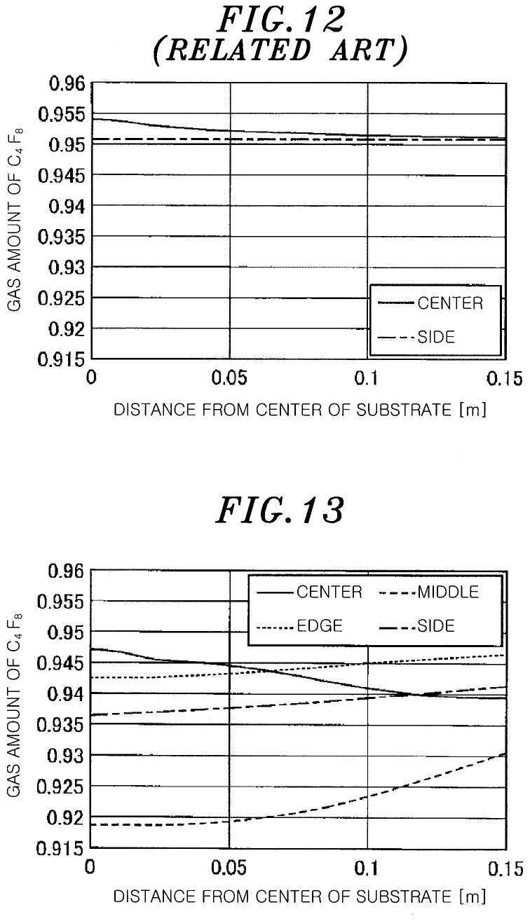

Next, the simulation result of the gas amount on the substrate W when using the gas injector 200 and the gas shower 201 will be compared with reference to FIGS. 12 and 13.

<Simulation Conditions>

Chamber pressure: 6.67 Pa (50 m Torr)

Main gas: C₄F₈=200 sccm

Sub-gas: Ar=50 sccm

(Total Flow Amount of Four Systems in the Gas Shower 201)

FIG. 12 shows an example of the simulation result in the second comparative Example. FIG. 13 shows an example of the simulation result in the first modification of the second embodiment. FIG. 12 shows the gas amount distribution of the main gas (C₄F₈) on the substrate W in the simulation of the second comparative example in which the main gas is supplied from each of the center nozzle and the side nozzle of the gas injector 200. FIG. 13 shows the gas amount distribution of the main gas (C₄F₈) on the substrate W in the simulation of the first modification of the second embodiment in which the main gas is supplied from each set of the center gas injection holes, the middle gas injection holes, the edge gas injection holes, and the side gas injection holes of the gas shower 201. Further, in order to prevent gas backflow, the sub-gas is supplied to the nozzle and the set(s) of the gas injection holes to which the main gas is not supplied. In the vertical axis of FIGS. 12 and 13, “1” indicates the case where the amount of C₄F₈ gas is 100% and “0” indicates the case where the amount of C₄F₈ gas is 0%.

According to the comparison of the gas amount distribution of the main gas (C₄F₈) on the substrate W between the second comparative example and the first modification of the second embodiment, in the second comparative example shown in FIG. 12, the difference in the amount of the main gas between the center and the edge is about 0.005 (0.5%) near the center of the substrate W and decreases toward the peripheral portion of the substrate W. In other words, the gas injector 200 has poor controllability for the gas amount of the main gas. In contrast, in the first modification of the second embodiment shown in FIG. 13, the difference in the amount of the main gas between the center, the middle, the edge, and the side is within a range of about 0.007 (0.7%) to about 0.028 (2.8%) near the center of the substrate W, and is within a range of about 0.002 (0.2%) to about 0.015 (1.5%) at the peripheral portion of the substrate W.

In other words, the gas shower 201 has a wider range of controlling the amount of the main gas, and thus has improved controllability. For example, as shown in FIG. 13, in the case of supplying the main gas from the center of the gas shower 201, it is possible to control the gas amount to be decreased toward the peripheral portion of the substrate W, as in the case of supplying the main gas from the center of the gas injector 200. On the other hand, in the case of supplying the main gas from the middle, the edge or the side of the gas shower 201, it is possible to control the gas amount to be increased toward the peripheral portion of the substrate W. In other words, in the first modification of the second embodiment, the controllability of the gas distribution on the substrate W can be further improved.

(Control of Flow Ratio)

The gas shower 201 can have further improved controllability by supplying the main gas from the plurality of gas injection holes at a controlled flow ratio. An example of controlling the flow ratio of the gas injection holes using the gas shower 201 will be described in comparison with the case of using the gas injector 200 with reference to FIGS. 14 to 19.

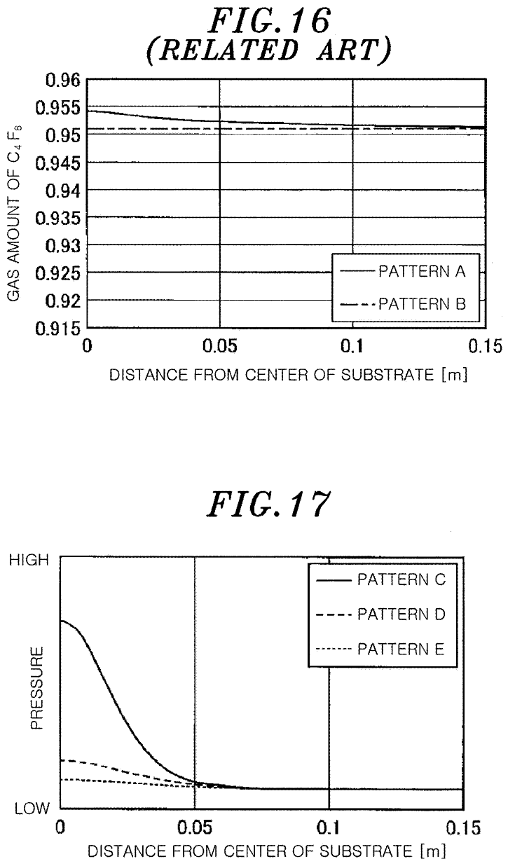

FIGS. 14 to 16 show examples of the simulation results in the second comparative example. FIGS. 17 to 19 show examples of the simulation results in the first modification of the second embodiment. FIGS. 14 to 16 show the distribution of the pressure, the flow velocity, and the amount of C₄Fₑ gas on the substrate W in the simulation of the second comparative example. FIGS. 14 to 16 show the case of supplying C₄F₈ gas of 200 sccm as the main gas from the center of the gas injector 200 and supplying Ar gas of 50 sccm as the sub-gas from the side (pattern A) of the gas injector 200, and the opposite case where the gas supplied from the center and the gas supplied from the side are switched with each other (Pattern B).

<Simulation Conditions for the Second Comparative Example>

Chamber pressure: 6.67 Pa (50 mTorr)

Main gas (C₄F₈): Center=200 sccm (Pattern A)
Side=200 sccm (Pattern B)

Sub-gas (Ar): Side=50 sccm (Pattern A)
Center=50 sccm (Pattern B)

FIGS. 17 to 19 show the distribution of the pressure, the flow velocity, and the amount of C₄F₈ gas on the substrate W in the simulation of the first modification of the second embodiment. In FIGS. 17 to 19, C₄F₈ gas was supplied as the main gas at a total flow rate of 200 sccm in three patterns, i.e., only from the center gas injection holes of the gas shower 201 (pattern C), from the center and the middle gas injection holes of the gas shower 201 (pattern D), and from the center, the middle, and the edge gas injection holes of the gas shower 201 (pattern E). Ar gas was supplied as the sub-gas at a total flow rate of 50 sccm from the other gas injection holes.

<Simulation Conditions for the First Modification of the Second Embodiment>

Chamber pressure: 6.67 Pa (50 mTorr)

Main gas (C₄F₈):
Center=200 sccm (Pattern C)
Center/Middle=100/100 sccm (Pattern D)
Center/Middle/Edge=66.7/66.7/66.7 sccm (Pattern E) Sub-gas (Ar):
Middle/Edge/Side=16.7/16.7/16.7 sccm (Pattern C)
Edge/Side=25/25 sccm (Pattern D)
Side=50 sccm (Pattern E)

According to the simulation results for the pressure on the substrate W between the second comparative example and the first modification of the second embodiment, in the pattern A of the second comparative example shown in FIG. 14, the pressure is highest near the center of the substrate W and decreases toward a portion separated from the center of the substrate W by a distance of about 5 cm. In other words, the pressure distribution has a convex shape at the central portion. In the pattern B, the pressure distribution is substantially uniform from the center of the substrate W to the peripheral portion of the substrate W. In contrast, in the first modification of the second embodiment shown in FIG. 17, the pattern C has the same distribution as that of the pattern A of the second comparative example, and the pattern E has a substantially uniform pressure distribution from the center of the substrate W to the peripheral portion of the substrate W. In the pattern D, the pressure near the center of the substrate W is slightly higher than that in the pattern E.

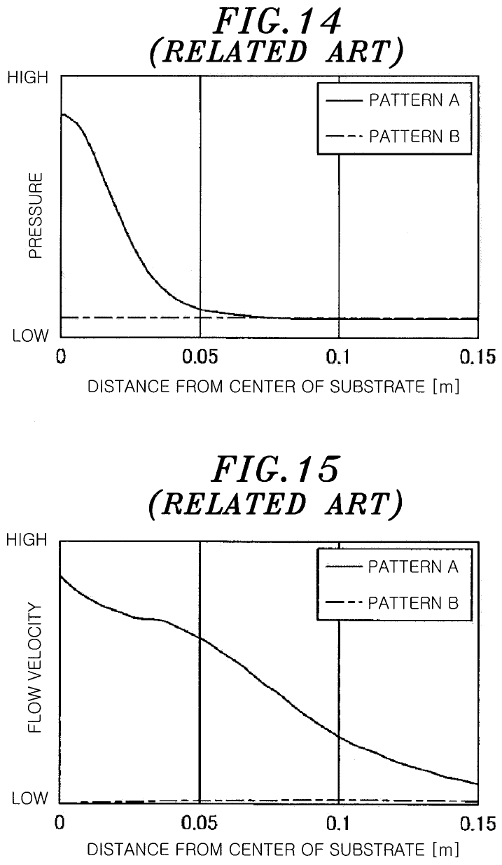

According to the simulation results for the flow velocity on the substrate W between the second comparative example and the first modification of the second embodiment, in the pattern A of the second comparative example shown in FIG. 15, the flow velocity decreases at a substantially uniform rate from the center of the substrate W to the peripheral portion of the substrate W. In the pattern B, the flow velocity distribution is substantially uniform from the center of the substrate W to the peripheral portion of the substrate W. In contrast, in the first modification of the second embodiment shown in FIG. 18, the pattern C has a distribution similar to that of the pattern A of the second comparative example. In the patterns D and E, the distribution has a slightly convex shape near a portion separated from the center of the substrate W by a distance of about 4 cm.

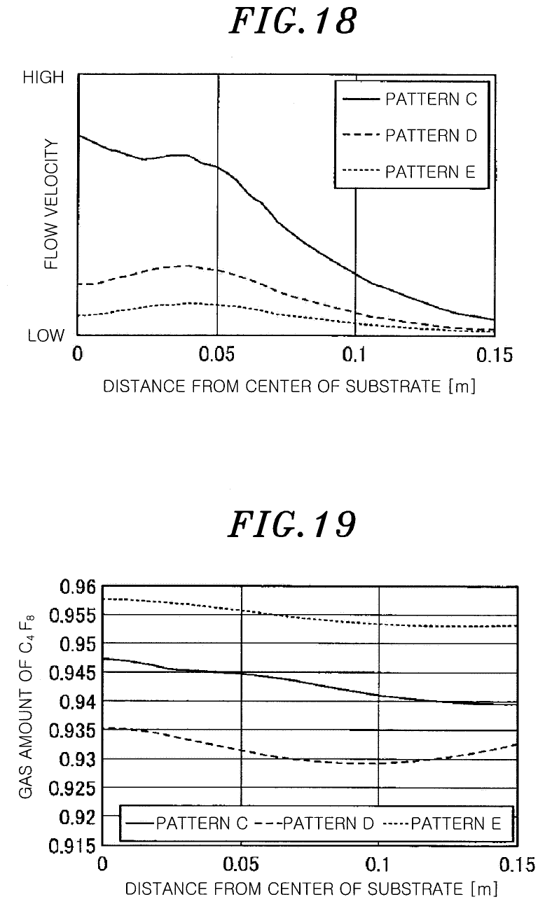

According to the simulation results for the gas amount distribution of the main gas (C₄F₈) between the second comparative example and the first modification of the second embodiment, in the second comparative example shown in FIG. 16, the difference between the patterns A and B is about 0.005 (0.5%) near the center of the substrate W and decreases toward the peripheral portion of the substrate W. In contrast, in the first modification of the second embodiment shown in FIG. 19, the difference in the amount of the main gas between the patterns D and E is about 0.023 (2.3%) near the center of the substrate W. Further, the difference in the amount of the main gas between the patterns D and E is about 0.02 (2%) near the peripheral portion of the substrate W. The amount of the main gas in the pattern C has a substantially intermediate value between those in the patterns D and E from the center of the substrate W to the peripheral portion of the substrate W. In other words, the gas shower 201 allows the fine control of the pressure, the flow velocity, and the gas amount of the main gas on the substrate W by controlling the flow ratio.

(Simulation Results of the Electromagnetic Field)

Next, the influence on the electromagnetic field distribution in a third comparative example and a second modification of the second embodiment will be described with reference to FIGS. 20 to 23. As described in the structure of the antenna 62, the outer coil 621 functions as a resonator and generates strong electric and magnetic fields. In contrast, the inner coil 622 is not connected to the first RF power supply 71 and has a closed loop. Further, the inner coil 622 is inductively coupled to the outer coil 621 to generate an induced electromotive force in the antenna. In other words, the inner coil 622 is an example of an absorbing coil. A variable capacitor 623 is connected to the inner coil 622, and the amount of current flowing through the inner coil 622 (hereinafter, also referred to as “amount of drawn current”) can be controlled by adjusting an impedance.

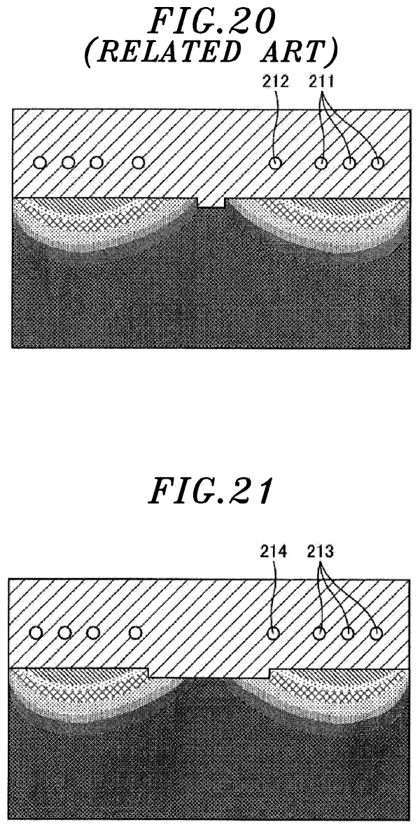

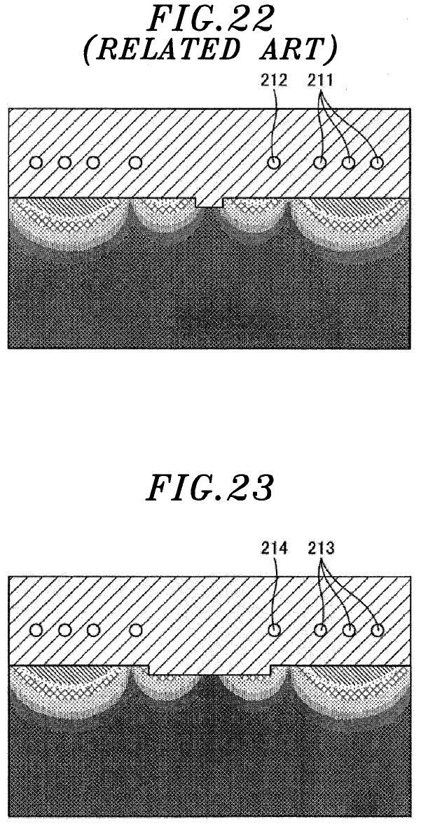

FIGS. 20 and 22 show examples of the simulation results of an electromagnetic field in the third comparative example. FIGS. 21 and 23 show examples of the simulation results of an electromagnetic field in the second modification of the second embodiment. In the third comparative example, an outer coil 211 and an inner coil 212 are used. In the second modification of the second embodiment, an outer coil 213 and an inner coil 214 are used instead of the outer coil 621 and the inner coil 622. In the third comparative example and the second modification of the second embodiment, the distances between the outer coil 211 and the bottom surface of the dielectric window and between the inner coil 212 and the bottom surface of the dielectric window are the same as the distances between the outer coil 213 and the bottom surface of the dielectric window and between the inner coil 214 and the bottom surface of the dielectric window.

FIGS. 20 and 21 show the electromagnetic field distribution of the plasma processing space 11s in the case where the amount of drawn current to the inner coils 212 and 214 is “0.” The electromagnetic field distribution of the plasma processing space 11s in the second modification of the second embodiment shown in FIG. 21 is substantially the same as the electromagnetic field distribution of the plasma processing space 11s in the third comparative example shown in FIG. 29. In other words, when the amount of drawn current is “0,” the electromagnetic field distribution is hardly affected even when the gas injector is changed to the gas shower.

FIGS. 22 and 23 show the electromagnetic field distribution of the plasma processing space 11s in the case where the amount of drawn current to the inner coils 212 and 214 is the maximum. The electromagnetic field distribution of the plasma processing space 11s in the second modification of the second embodiment shown in FIG. 23 is substantially the same as the electromagnetic field distribution of the plasma processing space 11s in the third comparative example shown in FIG. 22. In other words, when the amount of drawn current is the maximum, the electromagnetic field distribution is hardly affected even when the gas injector is changed to the gas shower.

As described above, in accordance with the first embodiment, the plasma processing apparatus 10 includes the chamber (the plasma processing chamber 11), the antenna assembly (the antenna 62), the primary coil (the outer coil 621), the RF power supply (the first RF power supply 71), and the gas shower 41. The chamber includes the sidewall and the ceiling plate (the dielectric window 61) having the central opening 61a, and the sidewall and the ceiling plate define the plasma processing space 11s. The antenna assembly is disposed above the ceiling plate. The antenna assembly includes the central region 62a, the first peripheral region 62b, and the second peripheral region 62c. The first peripheral region 62b surrounds the central region 62a, and the second peripheral region 62c surrounds the first peripheral region 62b. The central region 62a and the first peripheral region 62b vertically overlap the central opening 61a. The primary coil is disposed in the second peripheral region 62c. The RF power supply is configured to supply a RF signal to the primary coil. The gas shower 41 is disposed at the central opening 61a and has the bottom portion 44 exposed to the plasma processing space 11s. The bottom portion 44 has the plurality of bottom gas injection holes 46 and 47. Accordingly, the controllability of the gas distribution on the substrate W can be improved.

Further, in accordance with the first embodiment, the plasma processing apparatus 10 further includes the secondary coil (the inner coil 622) disposed in the first peripheral region 62b. The secondary coil is inductively coupled to the primary coil. Accordingly, plasma can be generated in the plasma processing space 11s.

Further, in accordance with the first embodiment, the secondary coil has a wire having two ends and the capacitor 623 connected to the two ends. Accordingly, the direction or the magnitude of the current flowing through the inner coil 622 can be controlled.

Further, in accordance with the first embodiment, the gas shower 41 has the side portion 45. At least a part of the side portion 45 is exposed to the plasma processing space 11s, and the side portion 45 has the plurality of side gas injection holes 48. Accordingly, the processing gas can be supplied in the horizontal direction.

Further, in accordance with the second embodiment, the plasma processing apparatus 10 further includes the gas distribution controller (the flow splitter 55). The gas shower 81 has the plurality of diffusion spaces (the gas diffusion spaces 83a and 83b). The gas distribution controller is configured to control the flow ratio of the gas distributed to the diffusion spaces, and each set of the bottom gas injection holes 86, the bottom gas injection holes 87, and the side gas injection holes 88 is in fluid communication with any one of the diffusion spaces. Accordingly, the controllability of the gas distribution on the substrate W can be further improved.

Further, in accordance with the second embodiment, the plasma processing apparatus 10 further includes the gas distribution controller (the flow splitter 55). The gas shower 201 includes the first diffusion space disposed at the center of the gas shower 201, the second diffusion space surrounding the first diffusion space, the third diffusion space surrounding the second diffusion space, and the fourth diffusion space surrounding the third diffusion space. The gas distribution controller is configured to control the flow ratio of the gas distributed to the first diffusion space, the second diffusion space, the third diffusion space, and the fourth diffusion space. Each set of the bottom gas injection holes 86a, the bottom gas injection holes 86b, and the bottom gas injection holes 87 is in fluid communication with any one of the first diffusion space, the second diffusion space, and the third diffusion space. The set of the side gas injection holes 88 is in fluid communication with the fourth diffusion space. Accordingly, the controllability of the gas distribution on the substrate W can be further improved.

Further, in accordance with the second embodiment, the set of the bottom gas injection holes 87 being in fluid communication with the third diffusion space is formed to extend obliquely. Accordingly, the controllability of the gas distribution on the substrate W can be further improved.

In accordance with the above-described embodiments, the bottom gas injection holes 46, 47, 86, and 87 have a first hole diameter of 0.05 mm to 1.5 mm and the side gas injection holes 48 and 88 have a second hole diameter of 0.05 mm to 1.5 mm. Accordingly, the flow rate or the flow velocity of the processing gas can be controlled by adjusting the conductance.

Further, in accordance with the above-described embodiments, the first hole diameter may be equal to the second hole diameter. Accordingly, it is possible to suppress the gas distribution having a convex shape at the central portion of the substrate W.

Further, in accordance with the above-described embodiments, the first hole diameter may be different from the second hole diameter. Accordingly, the flow rate or the flow velocity of the processing gas can be controlled by adjusting the conductance.

Further, in accordance with the above-described embodiments, the gas showers 41, 81, and 210 have a horizontal dimension and a vertical dimension smaller than the horizontal dimension. Accordingly, the controllability of the gas distribution on the substrate W can be further improved.

Further, in accordance with the above-described embodiments, the primary coil has a wire having two open ends, and the wire has a first contact point connected to the RF power supply and a second contact point that is grounded. Accordingly, a RF signal can be supplied to the primary coil.

The presently disclosed embodiments are considered in all respect to be illustrative and not restrictive. The above-described embodiments can be embodied in various forms. Further, the above-described embodiments may be omitted, replaced, or changed in various forms without departing from the scope of the appended claims and the gist thereof.

In the above-described embodiments, the spiral coil having open ends is used as the antenna 62. However, the antenna 62 is not limited thereto, and may be an antenna having another shape, for example, a coil having a wire whose one end is connected to the RF power supply and the other end is grounded, a loop-shaped coil, or the like.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A plasma processing apparatus comprising:
a chamber including a sidewall and a ceiling plate having a central opening, the sidewall and the ceiling plate defining a plasma processing space;
an antenna assembly disposed above the ceiling plate, the antenna assembly including a central region, a first peripheral region and a second peripheral region, the first peripheral region surrounding the central region, and the second peripheral region surrounding the first peripheral region, the central region and the first peripheral region vertically overlapping the central opening;
a primary coil disposed in the second peripheral region;
a radio frequency (RF) power supply configured to supply an RF signal to the primary coil; and
a gas shower disposed in the central opening, the gas shower having a bottom portion exposed to the plasma processing space, the bottom portion having bottom gas injection holes.

2. The plasma processing apparatus of claim 1, further comprising:
a secondary coil disposed in the first peripheral region and configured to be inductively coupled to the primary coil.

3. The plasma processing apparatus of claim 2, wherein the secondary coil has a wire having two ends and a capacitor connected to the two ends.

4. The plasma processing apparatus of claim 3, wherein the gas shower has a side portion, and at least a part of the side portion is exposed to the plasma processing space and has a plurality of side gas injection holes.

5. The plasma processing apparatus of claim 4, further comprising:
a gas distribution controller,
wherein the gas shower has a plurality of diffusion spaces,
the gas distribution controller is configured to control a flow ratio of a gas distributed to the diffusion spaces, and
one or more sets of the bottom gas injection holes and a set of the side gas injection holes are in fluid communication with the diffusion spaces, respectively.

6. The plasma processing apparatus of claim 4, further comprising:
a gas distribution controller,
wherein the gas shower includes a first diffusion space disposed at a center of the gas shower, a second diffusion space surrounding the first diffusion space, a third diffusion space surrounding the second diffusion space, and a fourth diffusion space surrounding the third diffusion space,
the gas distribution controller is configured to control a flow ratio of a gas distributed to the first diffusion space, the second diffusion space, the third diffusion space, and the fourth diffusion space, and
one or more sets of the bottom gas injection holes are in fluid communication with the first diffusion space, the second diffusion space, and the third diffusion space, respectively, and a set of the side gas injection holes is in fluid communication with the fourth diffusion space.

7. The plasma processing apparatus of claim 6, wherein the set of the bottom gas injection holes being in fluid communication with the third diffusion space is formed to extend obliquely.

8. The plasma processing apparatus of claim 7, wherein the bottom gas injection holes have a first hole diameter of 0.05 mm to 1.5 mm and the side gas injection holes have a second hole diameter of 0.05 mm to 1.5 mm.

9. The plasma processing apparatus of claim 8, wherein the first hole diameter is equal to the second hole diameter.

10. The plasma processing apparatus of claim 8, wherein the first hole diameter is different from the second hole diameter.

11. The plasma processing apparatus of claim 10, wherein the gas shower has a horizontal dimension and a vertical dimension smaller than the horizontal dimension.

12. The plasma processing apparatus of claim 11, wherein the primary coil has a wire having two open ends, and the wire has a first contact point connected to the RF power supply and a second contact point that is grounded.

13. The plasma processing apparatus of claim 1, wherein the gas shower has a side portion, and at least a part of the side portion is exposed to the plasma processing space and has a plurality of side gas injection holes.

14. The plasma processing apparatus of claim 13, further comprising:
a gas distribution controller,
wherein the gas shower has a plurality of diffusion spaces,
the gas distribution controller is configured to control a flow ratio of a gas distributed to the diffusion spaces, and
one or more sets of the bottom gas injection holes and a set of the side gas injection holes are in fluid communication with the diffusion spaces, respectively.

15. The plasma processing apparatus of claim 13, further comprising:
a gas distribution controller,
wherein the gas shower includes a first diffusion space disposed at a center of the gas shower, a second diffusion space surrounding the first diffusion space, a third diffusion space surrounding the second diffusion space, and a fourth diffusion space surrounding the third diffusion space,
the gas distribution controller is configured to control a flow ratio of a gas distributed to the first diffusion space, the second diffusion space, the third diffusion space, and the fourth diffusion space, and
one or more sets of the bottom gas injection holes are in fluid communication with the first diffusion space, the second diffusion space, and the third diffusion space, respectively, and a set of the side gas injection holes is in fluid communication with the fourth diffusion space.

16. The plasma processing apparatus of claim 15, wherein the set of the bottom gas injection holes being in fluid communication with the third diffusion space is formed to extend obliquely.

17. The plasma processing apparatus of claim 4, wherein the bottom gas injection holes have a first hole diameter of 0.05 mm to 1.5 mm and the side gas injection holes have a second hole diameter of 0.05 mm to 1.5 mm.

18. The plasma processing apparatus of claim 1, wherein the gas shower has a horizontal dimension and a vertical dimension smaller than the horizontal dimension.

19. The plasma processing apparatus of claim 1, wherein the primary coil has a wire having two open ends, and the wire has a first contact point connected to the RF power supply and a second contact point that is grounded.
